(19) United States
(12) Patent Application Publication
(10) Pub. No.: US 2024/0352597 A1
(43) Pub. Date: Oct. 24, 2024

(54) PHOTOELECTROCHEMICAL PRODUCTION OF HYDROGEN FROM WASTEWATER

(71) Applicant: SAUDI ARABIAN OIL COMPANY, Dhahran (SA)

(72) Inventors: Abeer ALARAWI, Dhahran (SA); Norah ALJURYYED, Dhahran (SA); Murtadha J. ALTAMMAR, Dhahran (SA)

(73) Assignee: SAUDI ARABIAN OIL COMPANY, Dhahran (SA)

(21) Appl. No.: 18/305,221

(22) Filed: Apr. 21, 2023

(51) Int. Cl. C25B 9/50; C02F 1/30; C02F 1/461; C02F 1/467; C25B 1/04; C25B 1/55; C25B 9/19; C25B 11/081; C25B 11/087; H01L 31/18

(52) U.S. Cl. CPC C25B 9/50; C02F 1/30; C02F 1/46109; C02F 1/4672; C25B 1/04; C25B 1/55; C25B 9/19; C25B 11/081; C25B 11/087; H01L 31/1804; C02F 2001/46142; C02F 2103/365; C02F 2201/46115; C02F 2305/10; H01L 31/109

(57) ABSTRACT

A photoelectrochemical system may be utilized for processing of wastewater to hydrogen. For example, a method for hydrogen production from wastewater may include: providing a photocathode electrically connected by a wire to a photocatalyst, where both the photocathode and the photocatalyst are at least partially immersed in an electrolyte solution that comprises an aqueous fluid having wastewater at least partially dissolved therein; illuminating the photocathode with first light thereby causing the photocathode to generate a first plurality of electron-electron hole pairs, wherein the photocathode comprises a silicon-based heterojunction; illuminating a photocatalyst with second light thereby causing the photocathode to generate a second plurality of electron-electron hole pairs, wherein the photocatalyst comprises a semiconductor; and photochemically converting the wastewater to hydrogen gas and oxygen.

### FIELD OF THE DISCLOSURE

The present disclosure relates generally to production of hydrogen and, more particularly, to photoelectrochemical production of hydrogen from wastewater.

### BACKGROUND OF THE DISCLOSURE

Hydrogen is an emerging clean fuel source with potential to power energy storage, electrical production, vehicle propulsion, and other applications. Hydrogen can be converted to usable energy (including electrical energy) with low or no emissions using technologies such as fuel cells where the product is water.

Methane derived from natural gas is the current conventional source for hydrogen production. Conventional methods of producing hydrogen include steam methane reforming (SMR), autothermal methane reforming (ATR), and partial oxidation of methane (POM). SMR, ATR and POM have a primary disadvantage of high CO₂ emissions that negate the clean-burning advantages of using hydrogen as a fuel source. Additional disadvantages of conventional hydrogen production methods include high energy consumption, high cost, low reaction efficiency, low process stability, and low efficiency of catalyst.

Wastewater (also referred to herein as “waste water”) may comprise any water that is discharged after use in areas including, but not limited to, refinery operations, industrial processes, and municipal wastewater. Wastewater may typically contain chemically hazardous, biohazardous, and/or otherwise toxic compounds, requiring significant treatment before release.

Photocatalysis is a reaction that uses light to activate a substance, which modifies the rate of a chemical reaction without being involved itself. The photocatalyst is the substance that can modify the rate of chemical reaction using light irradiation. A semiconductor photocatalyst has an energy band structure in which the conduction band and the valence band structure are separated by a forbidden band. When a photocatalyst is irradiated with light having energy equal to or higher than a band gap, electrons in the valence band are excited to the conduction band, while electron holes are generated in the valence band. The electrons excited to the conduction band have higher reducing power than that when the electrons are present in the valence band, and the holes have higher oxidizing power. The process allows the free-energy positive reaction (a thermodynamically unfavored reaction) to happen utilizing photon energy incident to a reactor device, allowing for solar energy conversion to chemical energy.

### SUMMARY OF THE DISCLOSURE

Various details of the present disclosure are hereinafter summarized to provide a basic understanding. This summary is not an exhaustive overview of the disclosure and is neither intended to identify certain elements of the disclosure, nor to delineate the scope thereof. Rather, the primary purpose of this summary is to present some concepts of the disclosure in a simplified form prior to the more detailed description that is presented hereinafter.

A nonlimiting method of the present disclosure includes: providing a photocathode electrically connected by a wire to a photocatalyst, where both the photocathode and the photocatalyst are at least partially immersed in an electrolyte solution that comprises an aqueous fluid having wastewater at least partially dissolved therein; illuminating the photocathode with first light thereby causing the photocathode to generate a first plurality of electron-electron hole pairs, wherein the photocathode comprises a silicon-based heterojunction; illuminating a photocatalyst with second light thereby causing the photocathode to generate a second plurality of electron-electron hole pairs, wherein the photocatalyst comprises a semiconductor; and photochemically converting the wastewater to hydrogen gas and oxygen.

A nonlimiting system of the present disclosure includes: a reaction chamber that contains an electrolyte solution, wherein the electrolyte solution comprises an aqueous fluid having wastewater at least partially dissolved therein; a photocathode at least partially immersed in the electrolyte solution, wherein the photocathode is capable of generating electron-electron hole pairs upon exposure to light, and wherein the photocathode comprises a silicon-based heterojunction; and a photocatalyst at least partially immersed in the electrolyte solution, wherein the photocatalyst is electrically connected to the photocathode, wherein the photocatalyst comprises a semiconductor, and wherein the photocatalyst is capable of generating electron-electron hole pairs upon exposure to light.

A nonlimiting method of fabricating a silicon-based heterojunction according to the present disclosure includes: etching, by electrodeless chemical process, micro-pyramid arrays in both sides of an n-type silicon wafer; forming a p+ emitter layer onto a face of the n-type silicon wafer by thermal diffusion; forming an n+ back surface field layer onto an opposing face of the n-type silicon wafer by thermal diffusion; depositing, on top of the p+ emitter layer, an Al₂O₃ layer by atomic layer deposition; depositing, on top of the Al₂O₃ layer, an Si₃N₄ layer by plasma-enhancer chemical vapor deposition; etching the Al₂O₃ layer and the Si₃N₄ layers with a patterned mask; and depositing a silver (Ag) layer on top of the Si₃N₄ layer.

Any combinations of the various embodiments and implementations disclosed herein can be used in a further embodiment, consistent with the disclosure. These and other aspects and features can be appreciated from the following description of certain embodiments presented herein in accordance with the disclosure and the accompanying drawings and claims.

### BRIEF DESCRIPTION OF THE DRAWINGS

FIG. 1 is diagram of a nonlimiting example of at least a portion of a photoelectrochemical water splitting unit according to the present disclosure.

FIG. 2 is a diagram of a nonlimiting example layered composition of a photocathode according to the present disclosure.

### DETAILED DESCRIPTION

Embodiments of the present disclosure will now be described in detail with reference to the accompanying Figures. Like elements in the various figures may be denoted by like reference numerals for consistency. Further, in the following detailed description of embodiments of the present disclosure, numerous specific details are set forth in order to provide a more thorough understanding of the claimed subject matter. However, it will be apparent to one of ordinary skill in the art that the embodiments disclosed herein may be practiced without these specific details. In other instances, well-known features have not been described in detail to avoid unnecessarily complicating the description. Additionally, it will be apparent to one of ordinary skill in the art that the scale of the elements presented in the accompanying Figures may vary without departing from the scope of the present disclosure.

Embodiments in accordance with the present disclosure generally relate to production of hydrogen and, more particularly, to photoelectrochemical production of hydrogen from wastewater.

The present disclosure includes systems and methods for conversion of light to hydrogen fuel through use of photoelectrocatalysis, in particular, photoelectrocatalysis of wastewater. The present disclosure provides for conversion of light energy (e.g., solar energy) directly into hydrogen fuel in a sustainable and low-emission (including low carbon dioxide emission) manner. The photoelectrochemical system of the present disclosure utilizes photoelectrocatalyst material including a co-catalyst that allows for efficient generation of hydrogen from wastewater. Additionally, the present disclosure may add value to processing of wastewater, as wastewater traditionally requires costly treatment that may generate significant toxic emissions, whereas the present disclosure allows for generation of hydrogen and may allow for at least partially removing impurities from said wastewater. As a result, the present disclosure may potentially decrease treatment costs of wastewater and add hydrogen production as an additional source of revenue.

The photocathode used in the photoelectrochemical systems of the present disclosure may comprise a silicon-based heterojunction. A silicon-based heterojunction may enable effective reaction in the photochemical cell while ensuring low cost due to the wide availability of silicon components. Additionally, without being bound by theory, silicon may maintain a band gap that is in alignment with the oxidation and reduction potentials of water, allowing silicon to operate effectively in photoelectrochemical cells with aqueous-based solutions.

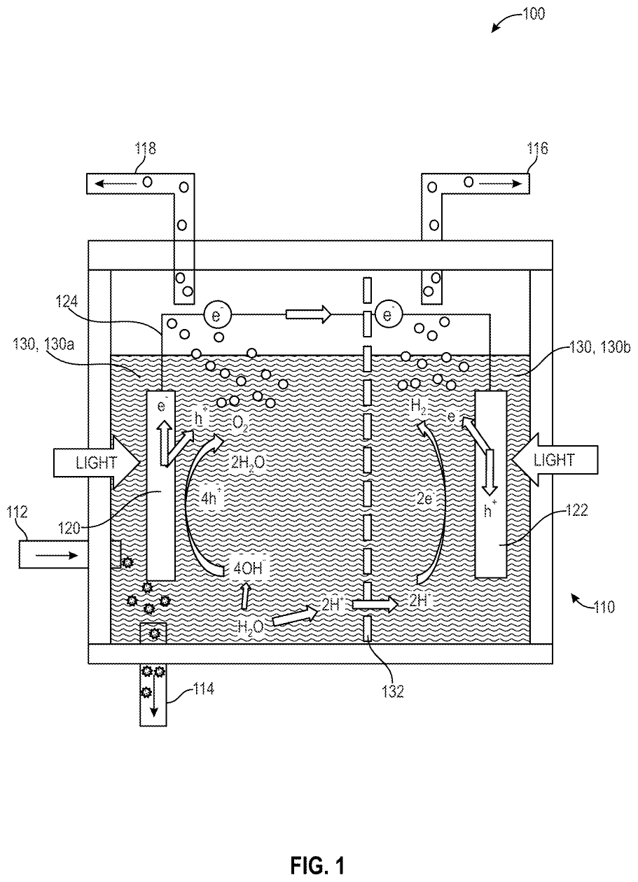

The system and methods may utilize a photoelectrochemical water splitting unit (also referred to herein as simply “unit.” “units,” or any grammatical variations thereof). A nonlimiting example of at least a portion of a photoelectrochemical water splitting unit 100 according to the present disclosure is shown in FIG. 1. The unit 100 includes a reaction chamber 110 having therein a photocatalyst 120 and a photocathode 122 connected by a wire 124 and immersed in an electrolyte solution 130.

The reaction chamber 110 may have one or more inlets (illustrated as a single inlet 112) for adding materials to the reaction chamber 110. Materials that may be introduced to the reaction chamber 110 via the one or more inlets may include, but are not limited to, a wastewater source, electrolyte solution 130 (or components thereof) (described in more detail below), the like, and any combination thereof.

The reaction chamber 110 may additionally have one or more outlets. In the illustrated example, the one or more outlets include a solids outlet 114 for removing precipitated waste and a hydrogen gas outlet 116 for evacuation of hydrogen gas from the reaction chamber 110, as well as an oxygen outlet 118 for evacuation of oxygen gas from the reaction chamber 110.

The reaction chamber 110 may furthermore have a semi-permeable membrane 132 (described in more detail below) fluidly separating the electrolyte solution 130a surrounding the photocatalyst 120 and the electrolyte solution 130b surrounding the photocathode 122. It should be noted that the semi-permeable membrane 132 may extend vertically through a portion of the reaction chamber 110, or may extend vertically from the top of the reaction chamber 110 to the bottom, as shown in FIG. 1.

The reaction chamber may be constructed of any suitable material and may be of any suitable size or configuration. At least a portion of the reaction chamber may be constructed of a material (e.g., glass, acrylic, a polymer, the like, or any combination thereof) that may at least partially light-transparent, allowing electromagnetic radiation (e.g. visible light, UV light, the like, or any combination thereof) into the reaction chamber for interaction with the photocatalyst and photocathode.

Returning to FIG. 1, the diagram additionally shows a nonlimiting example reaction mechanism for the production of hydrogen from wastewater. The mechanism described herein is not to be bound by theory. Light may enter the reaction chamber 110 as shown by the arrows labeled “LIGHT.” Upon contact with the photocatalyst 120, the light may excite the band gap and form an electron-electron hole pair, indicated by the formation of e⁻ and h⁺, respectively. The electron, e″, may be transferred to the photocathode 122 by the wire 124. In the presence of the electrolyte solution, water may disassociate into ions of OH⁻ and H⁺. The 4OH— ions may combine with 2h⁺ to form two (2) H₂O (water) molecules and one (1) O₂ (oxygen) molecule, the O₂ evolving out of the electrolyte solution. The H⁺ ions generated may transfer across the semi-permeable membrane 132 to the photocathode 122. Light contacting the photocathode 122 may additionally form an electron-electron hole pair, wherein the h+ is neutralized by e⁻ from the wire 124 (from the photocathode 122) and the e drives the formation of H₂. 2H⁺ ions react with 2e⁻ at the photocathode 122 to form H₂ gas, which evolves from the solution. The reactions shown in FIG. 1 and described above are additionally summarized in Equations 1-4 below. It should be, again, noted that additional reactions not shown or described may contribute to the production of hydrogen or otherwise be present in the above described system.

$${H}_{2} O \to {H}^{+} + {OH}^{-} \qquad Equation 1$$

$$LIGHT \to {h}^{+} + {e}^{-} \qquad Equation 2$$

$$4 {OH}^{-} + 4 {h}^{+} \to 2 {H}_{2} O + {O}_{2} \qquad Equation 3$$

$$2 {H}^{+} + 2 {e}^{-} \to {H}_{2} \qquad Equation 4$$

### Photocatalyst

The photocatalyst of the present disclosure may preferably comprise a semiconductor, thus forming a semiconductor photocatalyst. Any number of suitable semiconductor photocatalyst materials can be used in accordance with the present disclosure. For example, the semiconductor photocatalyst material can comprise one or more sulfides, including, but not limited to, CdS, MoS₂, FeS, CoS, NiS, MnS2, ZnS, ZnS₂, Cu₂S, Rh₂S, Ag₂S, HgS, In₂S₃, SnS₂, PbS, SnS₂, PbS, SnS, TiS, Sb₂S₃, RuS₂, the like, or any combination thereof. In a nonlimiting example, the semiconductor photocatalyst material may be in the form of a cadmium sulfide (CdS) material. As is known, cadmium sulfide may be a direct band gap semiconductor that functions as a photocatalyst, with a direct band gap of 2.4 eV and a light response to wavelengths in the range of visible light. The CdS material may be prepared using conventional techniques including but not limited to synthesizing techniques that produce CdS with high crystallinity (CdS nanocrystals).

The semiconductor photocatalyst material may also comprise one or more oxides, including, but not limited to, TiO₂, CoTiO₃, NiTiO₃, CuTiO₃, ZnTiO₃, V₂O₅, FeO₂, FeO₃, CuO, NiO, Cu₂O, ZnO, SrTiO₃, ZrO₂, Nb₂O₅, Ta₂O₅, or Bi₂W₂O₉, CeO₂, In₂O₃, WO₃, the like, or any combination thereof. Additionally, the semiconductor photocatalyst material may comprise one or more other semiconductor materials, including, but not limited to, CdSe, ZnSe, PbSe, Ag₂Sc, CuInS₂, CuInGaSe₂, ZnS₂CdSe, ZnCuS, AgIn₂S₂, Pt, the like, or any combination thereof. In a nonlimiting example, the semiconductor photocatalyst material may be in the form of a platinum (Pt) or a platinum alloy.

The photocatalyst may additionally comprise a sacrificial agent. The sacrificial agent may, without being bound by theory, promote H₂ production by reacting with photogenerated electron holes and preventing charge recombination between photogenerated electrons and electron holes. Any suitable sacrificial agent may be used. Suitable sacrificial agents may include, but are not limited to, a sulfide ion, a sulfite ion, triethanolamine (TEOA), ethanol, lignin, lactic acid, propanol, ethylene glycol the like, or any combination thereof.

### Photocathode

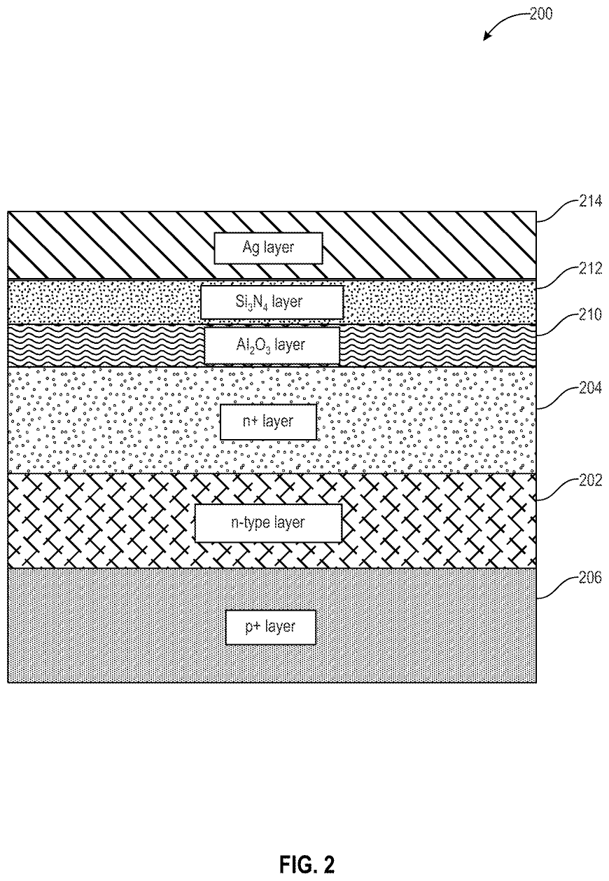

The photocathode of the present disclosure may comprise any suitable semiconductor, preferably a silicon-based semiconductor. The photocathode may comprise a silicon-based heterojunction. The silicon-based heterojunction may comprise a layered composition. A diagram of a nonlimiting example layered composition of the silicon-based heterojunction is shown in FIG. 2. Layered composition 200 includes a base n-type silicon layer 202 comprising crystalline silicon, sandwiched between an n+ layer of silicon 204 and a p+ layer of silicon 206, the n+ and p+ layers comprising thin film silicon, and the n+ layer 204 and p+ layer 206 being located on opposite faces of the n-type silicon layer 202. Layered composition 200 may furthermore comprise one or more additional layers, illustrated by layers 210, 212, and 214. In the presently described nonlimiting example three (3) additional layers are shown; however, one (1) or more, two (2) or more, or three (3) or more additional layers may be present. In the presently described nonlimiting example layer 210 comprises an Al₂O₃ layer, layer 212 comprises an Si₃N₄ layer, and layer 214 comprises an Ag (silver) layer.

The n-type silicon may comprise any suitable n-type of silicon including, but not limited to type 100 silicon wafers. The n-type silicon layer may have a thickness from 50 μm to 500 μm, or 50 μm to 200 μm, or 100 μm to 200 μm. The n-type silicon layer may include additional features including, but not limited to, micro-pyramid arrays, etchings, the like, or any combination thereof. The p+ silicon layer may comprise any suitable p+ type silicon. The p+ layer may have any suitable dopant concentration including, for example, a concentration of from 1×10¹⁵ cm⁻³ to 10×10²⁰ cm⁻³ (or 1×10¹⁸ cm⁻³ to 10×10²⁰ cm⁻³, or about 9×10¹⁹ cm⁻³). The p+ layer may have any suitable thickness including from 1 nm to 10,000 nm, or 1 nm to 1000 nm, or 1 nm to 500 nm, or 1 nm to 400 nm, or 100 nm to 400 nm, or 200 nm to 400 nm, or 250 nm to 350 nm, or 300 nm. The n+ silicon layer may comprise any suitable n+ type silicon. The n+ layer may have any suitable dopant concentration including, for example, a concentration of from 1×10¹⁵ cm⁻³ to 10×10²⁰ cm⁻³, (or 1×10¹⁸ cm⁻³ to 10×10²⁰ cm⁻³, or about 3×10²⁰ cm⁻³). The n+ layer may have any suitable thickness including from 1 nm to 10,000 nm, or 1 nm to 1000 nm, or 1 nm to 500 nm, or 1 nm to 400 nm, or 100 nm to 400 nm, or 200 nm to 400 nm, or 250 nm to 350 nm, or 300 nm.

The one or more additional layers of the silicon-based heterojunction may each comprise any suitable additional compounds such as a metal oxide, a metal, a metal alloy, a nitride, a semiconductor material, the like, or any combination thereof. The one or more additional layers may each have any suitable thickness including from 1 nm to 10,000 nm, or 1 nm to 1000 nm, or 1 nm to 500 nm, or 1 nm to 400 nm, or 100 nm to 400 nm, or 200 nm to 400 nm, or 250 nm to 350 nm, or 300 nm. It should be noted that for all of the layers described above, thicknesses outside the aforementioned ranges are additionally contemplated.

The silicon-based heterojunction may be manufactured using any suitable fabrication process. A nonlimiting example fabrication process of the silicon-based heterojunction for use as a photocathode includes wherein: micro-pyramid silicon arrays may be fabricated on both sides of a 150-μm-thick n-type (100) silicon wafer by electrodeless chemical etching in a solution of potassium hydroxide (45 vol %) and isopropyl alcohol (IPA). A 300 nm p+ emitter layer (dopant concentration of 9×1019 cm⁻³) may subsequently be formed by the thermal diffusion of BCl₃ onto the n-type layer. Furthermore, 300 nm of n+ back surface field layer (dopant concentration of 3×1020 cm⁻³) may be formed by thermal diffusion processes of POCl₄ on to the opposite side of the n-type layer as the p+ layer. 7 nm of Al₂O₃ may be deposited on top of the p+ layer, with 50 nm of Si₃N₄ deposited on top of the Al₂O₃. The Al₂O₃ and Si₃N₄ layers may be formed using atomic layer deposition and plasma-enhanced chemical vapor deposition, respectively. Furthermore, the Al₂O₃ and Si₃N₄ layers may be etched with hydrofluoric acid after the photolithography process using a patterned mask. Finally, 300 nm of Ag may deposited on top of the Si₃N₄ layer, followed by a lift-off process.

The photocathode of the present disclosure may further include a co-catalyst. The co-catalyst may comprise any suitable material that is chemically matching with the silicon-based heterojunction and maintains stability and efficiency during electrochemical operation. The co-catalyst may include, but is not limited to, metal alloys, chalcogenides, nitrides, phosphides, borides, sulfides, and carbides. The co-catalyst may comprise one or more of the additional layers described above, and may be further processed such as, for example, etched, patterned, or the like.

One skilled in the art should be able to, with the benefit of the present disclosure, select and/or construct a suitable photocathode including a silicon-based heterojunction (and, optionally, a co-catalyst) for use in the systems described herein.

### Semi-Permeable Membrane

Photoelectrochemical water splitting units of the present disclosure may include a semi-permeable membrane that may comprise a proton-exchange membrane in the interior of the reaction chamber, separating fluid between the photocatalyst and the photocatalyst. The proton-exchange membrane may be an ion exchange membrane that only permits one-way proton communication between the photocatalyst and the photocatalyst. The present disclosure may utilize any suitable proton-exchange membrane. Examples of suitable proton-exchange membranes materials may include, but are not limited to, perfluorinated polymer membranes (e.g., NAFION, available from Chemours).

### Electrolyte Solution

The electrolyte solution described above may comprise an aqueous fluid (e.g., water) and any suitable electrolyte salt. Suitable electrolyte salts may include, but are not limited to potassium chloride (KCl), potassium iodide (KI), sodium chloride (NaCl), ammonium chloride (NH₄Cl), potassium sulfonate (K₂SO₄), sodium sulfonate (Na₂SO⁴), ammonium sulfonate ((NH₄)₂SO₄), ethylenediaminetetraacetic acid (EDTA), ethylenediaminetetraacetic acid disodium salt (EDTA-2Na), ethylenediaminetetraacetic acid tetrasodium salt (EDTA-4Na), N-(2-hydroxyethyl)ethylenediamine-N,N′,N′-triacetic acid (HEDTA), N-(2-hydroxyethyl)ethylenediamine-N,N′,N′-triacetic acid trisodium salt (HEDTA-3Na), ciethylenetriaminepentaacetic acid (DTPA), ciethylenetriaminepentaacetic acid pentasodium salt (DTPA-5Na), 1,2-diaminocyclohexanetetraacetic acid (DCTA), 1,2-diaminocyclohexanetetraacetic acid disodium salt (DCTA-2Na), citric acid, sodium citrate, the like, or any combination thereof. The electrolyte may be present in any suitable concentration, including, for example, from 0 mol/L (M) to saturated (or 0.0001 M to saturated, or 0.01 M to 10 M, or 0.01 M to 5 M, or 0.01 M to 2 M, or 0.01 M to 1 M, or 0.1 M to 10 M, or 0.1 M to 5 M, or 0.1 M to 2 M, or 0.1 M to 1 M, or 1 M to 5 M, or 1 M to 2 M). “Saturated,” as used herein, refers to a concentration of a solution in which the maximum amount of solvent is dissolved at atmospheric pressure and 25° C.

It should be noted that when the photoanode comprises TiO₂, Fe₂O₃, the like, or a combination thereof, alkaline electrolytes may be preferably used in the electrolyte solution. Alkaline electrolytes may have a pH greater than 7, or preferably a pH of 10 or greater, or more preferably a pH of 12 or greater. Without being bound by theory, alkaline electrolytes may allow for increased stability of a photoanode comprising TiO₂, Fe₂O₃, the like, or a combination thereof. Additionally, when the photoanode comprises WO₃ or the like, neutral or acidic electrolytes may be preferably used in the electrolyte solution. A neutral or acidic electrolyte may have a pH of 7 or less. Without being bound by theory, neutral or acidic electrolytes may allow for increased stability of a photoanode comprising WO₃ or the like.

### Integrated System and Wastewater Sources

The photoelectrochemical water splitting units of the present disclosure may be constructed in a location so as to receive electromagnetic radiation (e.g., UV light, visible light) to the unit so as to excite the photocatalyst and the photocathode. The photocatalyst and photocathode may each be constructed so as to be excited by electromagnetic radiation with wavelengths from 1 nm to 1 mm, or 1 nm to 10 μm, or 1 nm to 1000 nm, or 10 nm to 1000 nm, or 100 nm to 900 nm, or 100 nm to 700 nm, or 100 nm to 5000 nm, or 100 nm to 1000 nm. The photocatalyst and photocathode may each be constructed so as to be excited by sunlight.

The units of the present disclosure may be integrated into any suitable application where processing of wastewater is desired, where production of hydrogen is desired, or both. As a nonlimiting example, one or more units may be integrated in a gas-oil separation plant (GOSP): the wastewater stream of a gas-oil separation plant allows for suitable supply of wastewater to the unit(s) and process disclosed herein. As another nonlimiting example, one or more units of the present disclosure may be integrated into a system for processing produced water from a hydraulic fracturing operation (e.g., slickwater (e.g., slickwater from a shale formation)). Other examples of wastewater sources may include, but are not limited to, backwater flow from a hydrocarbon well, produced water, pond water from a gas plant, seawater, the like, or any combination thereof.

Suitable wastewater for use in the present disclosure may preferably have a pH from 5 to 8. The wastewater may preferably be filtered to remove particulates. It should be noted that the type and source of wastewater, including chemical properties thereof, may affect the type and concentration of electrolyte to be used, based on factors of the wastewater including, but not limited to, pH, dissolved chemical concentration, dissolved chemical type, the like, or any combination thereof.

It should be noted that the one or more units described herein may be operated in any suitable manner, including any suitable configuration (e.g., in parallel, in series, the like, or a combination thereof) and including any suitable operational fashion (e.g., a continuous fashion, a batch-wise fashion, the like, or a combination thereof).

For the purpose of these simplified schematic illustrations and description, there may be additional valves, lines, pumps, sensors, controllers, wires, and the like that are customarily employed in photoelectrochemical operations that are well known to those of ordinary skill in the art that are not shown.

### ADDITIONAL EMBODIMENTS

Embodiment 1. A method comprising: providing a photocathode electrically connected by a wire to a photocatalyst, where both the photocathode and the photocatalyst are at least partially immersed in an electrolyte solution that comprises an aqueous fluid having wastewater at least partially dissolved therein; illuminating the photocathode with first light thereby causing the photocathode to generate a first plurality of electron-electron hole pairs, wherein the photocathode comprises a silicon-based heterojunction; illuminating a photocatalyst with second light thereby causing the photocathode to generate a second plurality of electron-electron hole pairs, wherein the photocatalyst comprises a semiconductor; and photochemically converting the wastewater to hydrogen gas and oxygen.
Embodiment 2. The method of Embodiment 1, wherein the silicon-based heterojunction comprises an n-type silicon layer with an n+ silicon layer on one face and a p+ silicon layer on an opposing face.
Embodiment 3. The method of Embodiment 2, wherein the n-type silicon layer comprises crystalline silicon, and wherein the n+ silicon layer and the p+ silicon layer each comprise thin-film silicon.
Embodiment 4. The method of any one of Embodiments 1-3, wherein the silicon-based heterojunction further comprises one or more layers located on top of the n+ silicon layer.
Embodiment 5. The method of Embodiment 4, wherein the one or more layers comprise an Al₂O₃ layer and an Si₃N₄ layer, and wherein the Al₂O₃ layer is located in between the Si₃N₄ layer and the n+ silicon layer.
Embodiment 6. The method of Embodiment 5, wherein the Al₂O₃ layer and the Si₃N₄ layer are etched using a pattern mask
Embodiment 7. The method of Embodiment 4 or 5, wherein the one or more layers comprises a silver layer.
Embodiment 8. The method of any one of Embodiments 1-7, wherein the silicon-based heterojunction comprises one or more layers with a micro-pyramid structure.
Embodiment 9. The method of any one of Embodiments 1-8, wherein the silicon-based heterojunction further comprises a co-catalyst.
Embodiment 10. The method of Embodiment 9, wherein the co-catalyst comprises a metal alloy, a chalcogenide, a nitride, a phosphide, a boride, a sulfide, a carbide, or any combination thereof.
Embodiment 11. The method of any one of Embodiments 1-10, wherein the semiconductor of the photocatalyst comprises CdS, MoS₂, FeS, CoS, NiS, MnS2, ZnS, ZnS₂, Cu₂S, Rh₂S, Ag₂S, HgS, In₂S₃, SnS₂, PbS, SnS₂, PbS, SnS, TiS, Sb₂S₃, RuS₂, TiO₂, CoTiO₃, NiTiO₃, CuTiO₃, ZnTiO₃, V₂O₅, FeO₂, FeO₃, CuO, NiO, Cu₂O, ZnO, SrTiO₃, ZrO₂, Nb₂O₅, Ta₂O₅, or Bi₂W₂O₉, CeO₂, In₂O₃, WO₃, CdSe, ZnSe, PbSe, Ag₂Se, CuInS₂, CuInGaSe₂, ZnS₂CdSe, ZnCuS, AgIn₂S₂. Pt, or any combination thereof.
Embodiment 12. The method of any one of Embodiments 1-10, wherein the semiconductor of the photocatalyst comprises platinum or a platinum alloy.
Embodiment 13. The method of any one of Embodiments 1-12, wherein the photocatalyst further comprises a sacrificial agent, wherein the sacrificial agent comprises a sulfide ion, a sulfite ion, triethanolamine (TEOA), ethanol, lignin, lactic acid, propanol, ethylene glycol, or any combination thereof.
Embodiment 14. The method of any one of Embodiments 1-13, wherein the first light and the second light each comprise electromagnetic radiation with a wavelength from 100 nm to 1000 nm.
Embodiment 15. The method of any one of Embodiments 1-14, wherein a source of the wastewater is of a waste stream of a gas-oil separation plant.
Embodiment 16. A system comprising: a reaction chamber that contains an electrolyte solution, wherein the electrolyte solution comprises an aqueous fluid having wastewater at least partially dissolved therein; a photocathode at least partially immersed in the electrolyte solution, wherein the photocathode is capable of generating electron-electron hole pairs upon exposure to light, and wherein the photocathode comprises a silicon-based heterojunction; and a photocatalyst at least partially immersed in the electrolyte solution, wherein the photocatalyst is electrically connected to the photocathode, wherein the photocatalyst comprises a semiconductor, and wherein the photocatalyst is capable of generating electron-electron hole pairs upon exposure to light.
Embodiment 17. The system of Embodiment 16, wherein the silicon-based heterojunction comprises one or more layers with a micro-pyramid structure.
Embodiment 18. The system of Embodiment 16 or 17, wherein the silicon-based heterojunction further comprises a co-catalyst.
Embodiment 19. The system of any one of Embodiments 16-18, wherein the silicon-based heterojunction comprises: an n-type silicon layer, an n+ silicon layer on one face of the n-type silicon layer, a p+ silicon layer on an opposing face of the silicon layer, an Al₂O₃ layer, wherein the Al₂O₃ layer is located on top of the n+ silicon layer, an Si₃N₄ layer, wherein the Si₃N₄ layer is located on top of the Al₂O₃ layer, and a silver (Ag) layer located on top of the Si₃N₄ layer.
Embodiment 20. A method of fabricating a silicon-based heterojunction, the method comprising: etching, by electrodeless chemical process, micro-pyramid arrays in both sides of an n-type silicon wafer; forming a p+ emitter layer onto a face of the n-type silicon wafer by thermal diffusion; forming an n+ back surface field layer onto an opposing face of the n-type silicon wafer by thermal diffusion; depositing, on top of the p+ emitter layer, an Al₂O₃ layer by atomic layer deposition; depositing, on top of the Al₂O₃ layer, an Si₃N₄ layer by plasma-enhancer chemical vapor deposition; etching the Al₂O₃ layer and the Si₃N₄ layers with a patterned mask; and depositing a silver (Ag) layer on top of the Si₃N₄ layer.
Embodiment 21. The silicon-based heterojunction of Embodiment 20 formed to a photocathode for producing hydrogen from wastewater.

The terminology used herein is for the purpose of describing particular embodiments only and is not intended to be limiting of the invention. As used herein, for example, the singular forms “a,” “an,” and “the” are intended to include the plural forms as well, unless the context clearly indicates otherwise. It will be further understood that the terms “contains,” “containing,” “includes,” “including,” “comprises,” and/or “comprising,” and variations thereof, when used in this specification, specify the presence of stated features, integers, steps, operations, elements, and/or components, but do not preclude the presence or addition of one or more other features, integers, steps, operations, elements, components, and/or groups thereof.

Terms of orientation used herein are merely for purposes of convention and referencing and are not to be construed as limiting. However, it is recognized these terms could be used with reference to an operator or user. Accordingly, no limitations are implied or to be inferred. In addition, the use of ordinal numbers (e.g., first, second, third, etc.) is for distinction and not counting. For example, the use of “third” does not imply there must be a corresponding “first” or “second.” Also, if used herein, the terms “coupled.” or “coupled to,” or “connected,” or “connected to,” or “attached,” or “attached to” may indicate establishing either a direct or indirect connection, and is not limited to either unless expressly referenced as such.

While the disclosure has described several exemplary embodiments, it will be understood by those skilled in the art that various changes can be made, and equivalents can be substituted for elements thereof, without departing from the spirit and scope of the invention. In addition, many modifications will be appreciated by those skilled in the art to adapt a particular instrument, situation, or material to embodiments of the disclosure without departing from the essential scope thereof. Therefore, it is intended that the invention not be limited to the particular embodiments disclosed, or to the best mode contemplated for carrying out this invention, but that the invention will include all embodiments falling within the scope of the appended claims. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

What is claimed is:

1. A method comprising:
providing a photocathode electrically connected by a wire to a photocatalyst, where both the photocathode and the photocatalyst are at least partially immersed in an electrolyte solution that comprises an aqueous fluid having wastewater at least partially dissolved therein;
illuminating the photocathode with first light thereby causing the photocathode to generate a first plurality of electron-electron hole pairs, wherein the photocathode comprises a silicon-based heterojunction;
illuminating a photocatalyst with second light thereby causing the photocathode to generate a second plurality of electron-electron hole pairs, wherein the photocatalyst comprises a semiconductor; and
photochemically converting the wastewater to hydrogen gas and oxygen.

2. The method of claim 1, wherein the silicon-based heterojunction comprises an n-type silicon layer with an n+ silicon layer on one face and a p+ silicon layer on an opposing face.

3. The method of claim 2, wherein the n-type silicon layer comprises crystalline silicon, and wherein the n+ silicon layer and the p+ silicon layer each comprise thin-film silicon.

4. The method of claim 1, wherein the silicon-based heterojunction further comprises one or more layers located on top of the n+ silicon layer.

5. The method of claim 4, wherein the one or more layers comprise an Al₂O₃ layer and an Si₃N₄ layer, and wherein the Al₂O₃ layer is located in between the Si₃N₄ layer and the n+ silicon layer.

6. The method of claim 5, wherein the Al₂O₃ layer and the Si₃N₄ layer are etched using a pattern mask

7. The method of claim 4, wherein the one or more layers comprises a silver layer.

8. The method of claim 1, wherein the silicon-based heterojunction comprises one or more layers with a micro-pyramid structure.

9. The method of claim 1, wherein the silicon-based heterojunction further comprises a co-catalyst.

10. The method of claim 9, wherein the co-catalyst comprises a metal alloy, a chalcogenide, a nitride, a phosphide, a boride, a sulfide, a carbide, or any combination thereof.

11. The method of claim 1, wherein the semiconductor of the photocatalyst comprises CdS, MoS₂, FeS, CoS, NiS, MnS2, ZnS, ZnS₂, Cu₂S, Rh₂S, Ag₂S, HgS, In₂S₃, SnS₂, PbS, SnS₂, PbS, SnS, TiS, Sb₂S₃, RuS₂, TiO₂, CoTiO₃, NiTiO₃, CuTiO₃, ZnTiO₃, V₂O₅, FeO₂, FeO₃, CuO, NiO, Cu₂O, ZnO, SrTiO₃, ZrO₂, Nb₂O₅, Ta₂O₅, or Bi₂W₂O₉, CeO₂, In₂O₃, WO₃, CdSe, ZnSe, PbSe, Ag₂Se, CuInS₂, CuInGaSe₂, ZnS₂CdSe, ZnCuS, AgIn₂S₂, Pt, or any combination thereof.

12. The method of claim 1, wherein the semiconductor of the photocatalyst comprises platinum or a platinum alloy.

13. The method of claim 1, wherein the photocatalyst further comprises a sacrificial agent, wherein the sacrificial agent comprises a sulfide ion, a sulfite ion, triethanolamine (TEOA), ethanol, lignin, lactic acid, propanol, ethylene glycol, or any combination thereof.

14. The method of claim 1, wherein the first light and the second light each comprise electromagnetic radiation with a wavelength from 100 nm to 1000 nm.

15. The method of claim 1, wherein a source of the wastewater is of a waste stream of a gas-oil separation plant.

16. A system comprising:
a reaction chamber that contains an electrolyte solution, wherein the electrolyte solution comprises an aqueous fluid having wastewater at least partially dissolved therein;
a photocathode at least partially immersed in the electrolyte solution, wherein the photocathode is capable of generating electron-electron hole pairs upon exposure to light, and wherein the photocathode comprises a silicon-based heterojunction; and
a photocatalyst at least partially immersed in the electrolyte solution, wherein the photocatalyst is electrically connected to the photocathode, wherein the photocatalyst comprises a semiconductor, and wherein the photocatalyst is capable of generating electron-electron hole pairs upon exposure to light.

17. The system of claim 16, wherein the silicon-based heterojunction comprises one or more layers with a micro-pyramid structure.

18. The system of claim 16, wherein the silicon-based heterojunction comprises:
an n-type silicon layer,
an n+ silicon layer on one face of the n-type silicon layer,
a p+ silicon layer on an opposing face of the silicon layer,
an Al₂O₃ layer, wherein the Al₂O₃ layer is located on top of the n+ silicon layer, an Si₃N₄ layer, wherein the Si₃N₄ layer is located on top of the Al₂O₃ layer, and a silver (Ag) layer located on top of the Si₃N₄ layer.

19. A method of fabricating a silicon-based heterojunction, the method comprising:
etching, by electrodeless chemical process, micro-pyramid arrays in both sides of an n-type silicon wafer;
forming a p+ emitter layer onto a face of the n-type silicon wafer by thermal diffusion;
forming an n+ back surface field layer onto an opposing face of the n-type silicon wafer by thermal diffusion;
depositing, on top of the p+ emitter layer, an Al₂O₃ layer by atomic layer deposition;
depositing, on top of the Al₂O₃ layer, an Si₃N₄ layer by plasma-enhancer chemical vapor deposition;
etching the Al₂O₃ layer and the Si₃N₄ layers with a patterned mask; and
depositing a silver (Ag) layer on top of the Si₃N₄ layer.

20. The silicon-based heterojunction of claim 19 formed to a photocathode for producing hydrogen from wastewater.
